(19) United States
(12) Patent Application Publication
(10) Pub. No.: US 2026/0194345 A1
(43) Pub. Date: Jul. 9, 2026

(54) INFORMATION PROCESSING APPARATUS, SUBSTRATE PROCESSING APPARATUS, AND FILM THICKNESS PREDICTION METHOD

(71) Applicant: Tokyo Electron Limited, Tokyo (JP)

(72) Inventors: Shingo NISHIMOTO, Yamanashi (JP); Atsushi SHIGENOBU, Yamanashi (JP); Shota YAMAZAKI, Hokkaido (JP)

(21) Appl. No.: 19/441,039

(22) Filed: Jan. 6, 2026

(30) Foreign Application Priority Data
Jan. 8, 2025 (JP) 2025-002932

(51) Int. Cl. G01B 21/08

(52) U.S. Cl. CPC G01B 21/08

(57) ABSTRACT

An information processing apparatus includes: an acquisition unit that acquires measured film thickness data of a plurality of measurement points on a substrate surface with a film formed thereon by a substrate processing apparatus; a prediction model generation unit that generates a prediction model by regressing the measured film thickness data using Zernike polynomials; a prediction unit that predicts film thickness data of a plurality of prediction points on the substrate surface using the prediction model, and outputs the predicted film thickness data; and a display control unit that displays the predicted film thickness data on an output device.

### CROSS REFERENCES TO RELATED APPLICATIONS

This application is based on and claims priority from Japanese Patent Application No. 2025-002932, filed on Jan. 8, 2025, with the Japan Patent Office, the disclosure of which is incorporated herein in its entirety by reference.

### TECHNICAL FIELD

The present disclosure relates to an information processing apparatus, a substrate processing apparatus, and a film thickness prediction method.

### BACKGROUND

A film forming process is performed on a substrate in a substrate processing apparatus. The thickness of the film formed on the substrate is measured using a measurement device such as a film thickness gauge after the film forming process is completed (see, e.g., Japanese Patent Laid-Open Publication No. 2024-140711).

The film thickness value measured by the measurement device is used as a quality control indicator. Generally, since measuring the film thickness is time-consuming, the number of measurement points on the substrate surface subjected to the film thickness measurement in a mass production process is fewer than the number of measurement points on the substrate surface subjected to the film thickness measurement in an evaluation process.

### SUMMARY

According to an aspect of the present disclosure, an information processing apparatus includes: an acquisition unit that acquires measured film thickness data of a plurality of measurement points on a substrate surface with a film formed thereon by a substrate processing apparatus; a prediction model generation unit that generates a prediction model by regressing the measured film thickness data using Zernike polynomials; a prediction unit that predicts film thickness data of a plurality of prediction points on the substrate surface using the prediction model, and outputs the predicted film thickness data; and a display control unit that displays the predicted film thickness data on an output device.

The foregoing summary is illustrative only and is not intended to be in any way restricting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an example of a configuration of a film thickness prediction system according to an embodiment of the present disclosure.

FIG. 2 is a view illustrating an example of a hardware configuration of a computer.

FIG. 3 is a view illustrating an example of a problem occurring in a substrate mass production process.

FIG. 4 is a view illustrating an example of a problem occurring in the substrate mass production process.

FIG. 5 is a view illustrating an example of a film thickness prediction function that predicts film thickness data of arbitrary coordinates with higher accuracy from a small number of measured film thickness data.

FIG. 6 is a view illustrating an example of a film thickness prediction function that predicts film thickness data around chips with higher accuracy from measured film thickness data in a mass production process.

FIG. 7 is a functional block diagram illustrating an example of an apparatus controller according to an embodiment of the present disclosure.

FIG. 8 is a flowchart illustrating an example of a process performed by the film thickness prediction system according to an embodiment of the present disclosure.

FIG. 9 is a view illustrating an example of an algorithm of the film thickness prediction function.

FIG. 10 is a view illustrating an example of an algorithm of the film thickness prediction function.

FIGS. 11A and 11B are views illustrating an example of an algorithm of the film thickness prediction function.

FIGS. 12A and 12B are views illustrating an example of an algorithm of the film thickness prediction function.

FIGS. 13A to 13C are views illustrating an example of an algorithm of the film thickness prediction function.

FIGS. 14A to 14C are graph views illustrating an example of a comparison of predicted values and actual values between statistical values of in-plane film thickness of a substrate based on actual values of 49 points and statistical values of the in-plane film thickness of the substrate based on predicted values of 49 points.

### DETAILED DESCRIPTION

In the following detailed description, reference is made to the accompanying drawings, which form a part hereof. The illustrative embodiments described in the detailed description, drawings, and claims are not meant to be limiting. Other embodiments may be utilized, and other changes may be made without departing from the spirit or scope of the subject matter presented here.

Hereinafter, an embodiment of the present disclosure will be described with reference to the drawings.

### <System Configuration>

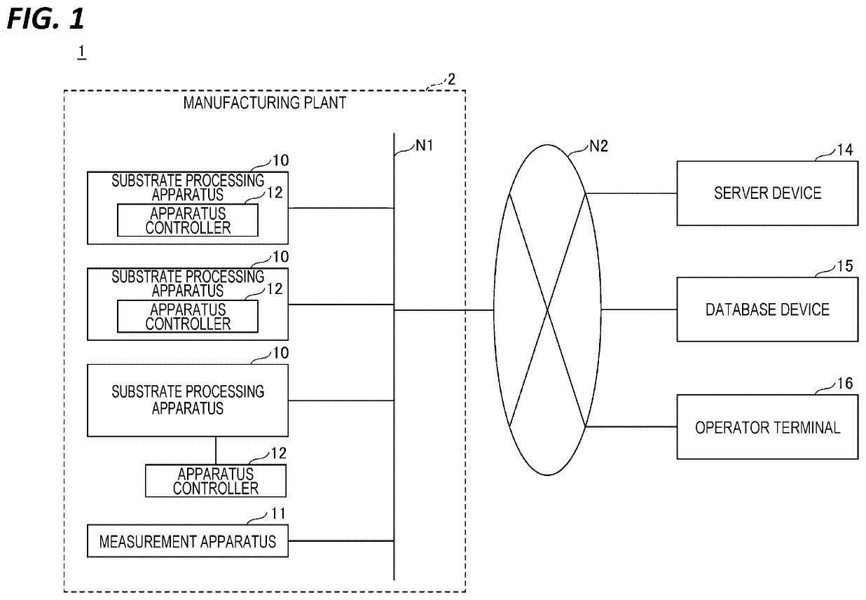

FIG. 1 is a view illustrating an example of the configuration of a film thickness prediction system according to an embodiment of the present disclosure. As illustrated in FIG. 1, a film thickness prediction system 1 includes a substrate processing apparatus 10, a measurement apparatus 11, an apparatus controller 12, a server device 14, a database device 15, and an operator terminal 16. The substrate processing apparatus 10, the measurement apparatus 11, and the apparatus controller 12 are installed in a manufacturing plant 2. The server device 14, the database device 15, and the operator terminal 16 may be installed in or outside the manufacturing plant 2. The substrate processing apparatus 10, the measurement apparatus 11, the apparatus controller 12, the server device 14, the database device 15, and the operator terminal 16 are connected to each other for communication via networks N1 and N2 such as the Internet and a local area network (LAN).

The substrate processing apparatus 10 performs a film formation on the surface of a substrate such as a wafer. The substrate processing apparatus 10 performs a process of forming a film on the substrate surface. The substrate processing apparatus 10 performs the process of forming a film on the substrate surface according to a process recipe that specifies process steps. The substrate processing apparatus 10 may be a film formation apparatus, a semiconductor manufacturing apparatus, or a heat treatment apparatus.

The substrate processing apparatus 10 receives control commands in accordance with a process recipe from the apparatus controller 12, and performs the process of forming a film on the substrate surface. As illustrated in FIG. 1, the substrate processing apparatus 10 may be equipped therein with the apparatus controller 12, or may not necessarily be equipped with the apparatus controller 12 as long as the substrate processing apparatus 10 is connected to the apparatus controller 12 in a communicable manner. The apparatus controller 12 outputs the control commands to control adjustment items (e.g., control components) of the substrate processing apparatus 10 according to the process recipe, thereby causing the substrate processing apparatus 10 to perform the process in accordance with the process recipe. The apparatus controller 12 has a man-machine interface function that receives instructions for the substrate processing apparatus 10 from an operator, and provides information on the substrate processing apparatus 10 to the operator. The apparatus controller 12 executes processes by acquiring various types of information necessary for the process executed by the film thickness prediction system 1 according to the present embodiment, from the substrate processing apparatus 10, the measurement apparatus 11, the server device 14, the database device 15, or the operator terminal 16.

The measurement apparatus 11 measures film thickness data of a plurality of measurement points on the substrate surface on which a film is formed by the substrate processing apparatus 10. Hereinafter, the film thickness data of the measurement points on the substrate surface that are measured by the measurement apparatus 11 will be referred to as measured film thickness data. The measured film thickness data represent the attachment state of the film onto the substrate surface that is measured by the measurement apparatus 11.

The measurement apparatus 11 may transmit the measured film thickness data to the substrate processing apparatus 10, the apparatus controller 12, the server device 14, the database device 15, or the operator terminal 16 via the networks N1 and N2. The operator may provide the measured film thickness data to the substrate processing apparatus 10, the apparatus controller 12, the server device 14, the database device 15, or the operator terminal 16, using a portable storage device such as a USB (Universal Serial Bus) memory.

Generally, it takes a long time to measure the film thickness data using the measurement apparatus 11. Thus, in the substrate mass production process such as a semiconductor manufacturing process, the film thickness data are measured at a smaller number of measurement points on the substrate surface, for example, 13 measurement points, than the number of measurement points in an evaluation process (e.g., 49 measurement points).

The database device 15 stores and manages various types of information necessary for the process executed by the film thickness prediction system 1 according to the present embodiment. The database device 15 may store and manage measured film thickness data of measurement points in past evaluation processes, as validation data.

The server device 14 executes processes by acquiring various types of information necessary for the process executed by the film thickness prediction system 1 according to the present embodiment, from the substrate processing apparatus 10, the measurement apparatus 11, the apparatus controller 12, the database device 15, or the operator terminal 16.

The operator terminal 16 is, for example, a personal computer (PC) or a smartphone operated by the operator such as an apparatus operator or an analysis personnel of the substrate processing apparatus 10. For example, the operator terminal 16 executes processes by acquiring various types of information necessary for the process executed by the film thickness prediction system 1 according to the present embodiment, from the substrate processing apparatus 10, the measurement apparatus 11, the apparatus controller 12, the server device 14, or the database device 15. The operator terminal 16 may transmit contents of an operation by the operator to the apparatus controller 12 or the server device 14, and may receive and display process results from the apparatus controller 12 or the server device 14.

The film thickness prediction system 1 of FIG. 1 is an example, and various examples of system configuration may be conceived according to applications or purposes. At least part of the process executed by the server device 14 may be executed by the apparatus controller 12 or the operator terminal 16. The apparatus controller 12, the server device 14, or the operator terminal 16 is an example of an information processing apparatus that performs a film thickness prediction method of the present embodiment. The substrate processing apparatus 10 equipped with the apparatus controller 12 is an example of the substrate processing apparatus 10 that performs the film thickness prediction method of the present embodiment. The server device 14 may be implemented by a plurality of information processing apparatuses or as a cloud computing service.

The film thickness prediction system 1 of FIG. 1 may be implemented by a stand-alone substrate processing apparatus 10 and an apparatus controller 12. The film thickness prediction system 1 may have a configuration where at least some of the server device 14, the database device 15, and the operator terminal 16 are integrated, a configuration where the devices are further divided, or a configuration where parts of the devices are omitted.

### <Hardware Configuration>

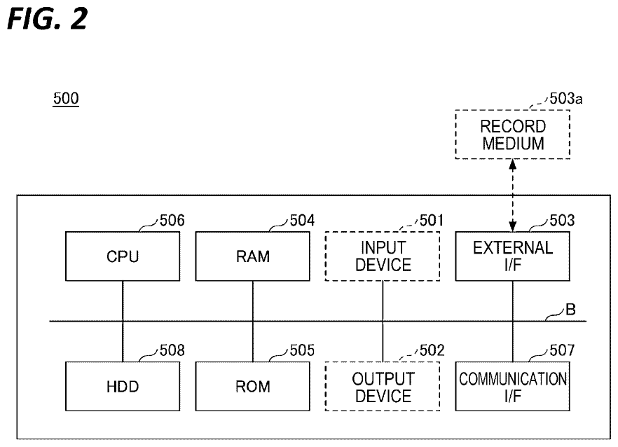

The apparatus controller 12, the server device 14, the database device 15, and the operator terminal 16 are implemented by, for example, a computer 500 having the hardware configuration of FIG. 2. FIG. 2 is a view illustrating an example of the hardware configuration of the computer 500.

The computer 500 of FIG. 2 includes, for example, an input device 501, an output device 502, an external I/F (interface) 503, a random access memory (RAM) 504, a read only memory (ROM) 505, a central processing unit (CPU) 506, a communication I/F 507, and a hard disk drive (HDD) 508, which are connected to each other via a bus B. The input device 501 and the output device 502 may be connected and used when necessary.

The input device 501 is, for example, a keyboard, a mouse, or a touch panel, and is used by, for example, the operator to input operation signals. The output device 502 is, for example, a display, and displays results of processes executed by the computer 500. The communication I/F 507 is an interface that connects the computer 500 to the networks N1 and N2. The HDD 508 is an example of a nonvolatile storage device that stores programs or data. The CPU 506 is an example of a processor, and may include devices such as a graphics processing unit (GPU).

The external I/F 503 is an interface with external devices. The computer 500 may perform reading and/or writing of a record medium 503a such as a secure digital (SD) memory card via the external I/F 503. The ROM 505 is an example of a nonvolatile semiconductor memory (storage device) that stores programs or data. The RAM 504 is an example of a volatile semiconductor memory (storage device) that temporarily holds programs or data.

The CPU 506 is a calculation device that reads programs or data from the storage device such as the ROM 505 or the HDD 508 onto the RAM 504, and executes processes to implement the control and the functions of the entire computer 500. The CPU 506 is an example of a processor, and may include devices such as a graphics processing unit (GPU).

The apparatus controller 12, the server device 14, the database device 15, and the operator terminal 16 illustrated in FIG. 1 may implement various functions to be described herein later, for example, by executing programs on the computer 500 having the hardware configuration of FIG. 2.

### <Problem Occurring in Mass Production Process>

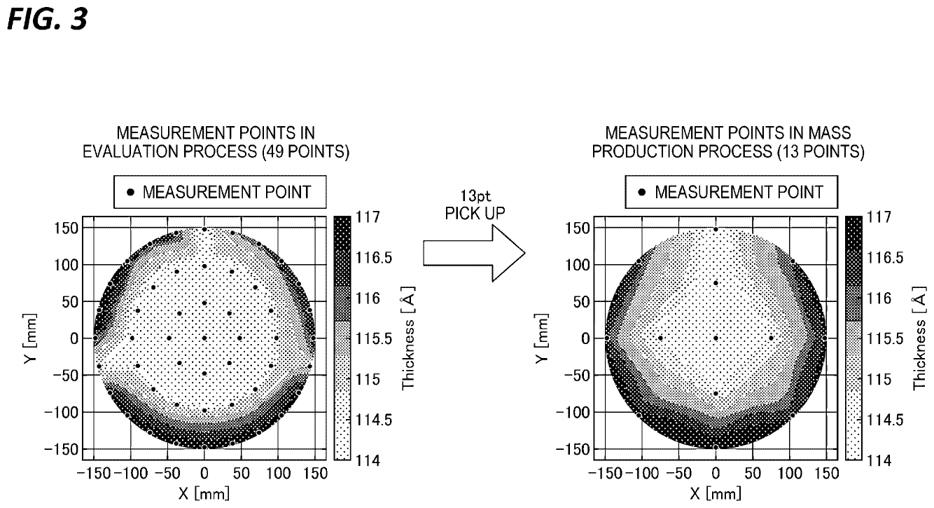

FIG. 3 is a view illustrating an example of a problem occurring in the substrate mass production process. For example, in the substrate evaluation process, the number of measurement points on the substrate surface is 49. Meanwhile, in the substrate mass production process, the number of measurement points on the substrate surface is 13. In consideration of the time consumed to measure the film thickness data, the number of measurement points in the substrate mass production process is generally fewer than the number of measurement points in the substrate evaluation process.

Since the number of measurement points in the substrate mass production process is fewer than the number of measurement points in the substrate evaluation process, statistical values (e.g., film thickness average, Range, or in-plane uniformity) of the film thickness on the substrate surface (e.g., in-plane film thickness) based on the film thickness data of the measurement points in the mass production process may differ from statistical values of the in-plane film thickness based on the film thickness data of the measurement points in the evaluation process.

Thus, the statistical values of the in-plane film thickness based on the film thickness data of the measurement points in the mass production process may become unsuitable for use as the quality control indicator. Further, when interpolating the in-plane film thickness using the film thickness data of the measurement points in the mass production process, the accuracy may deteriorate, as compared to when interpolating the in-plane film thickness using the film thickness data of the measurement points in the evaluation process. FIG. 3 represents that the result of prediction of the in-plane film thickness when the film thickness data of areas other than the measurement points are interpolated based on the film thickness data of the 49 measurement points in the evaluation process differs from the result of prediction of the in-plane film thickness when the film thickness data of areas other than the measurement points are interpolated based on the film thickness data of the 13 measurement points in the mass production process. As the number of measurement points on the substrate surface decreases, the accuracy of the interpolation result of the film thickness data of areas other than measurement points deteriorates.

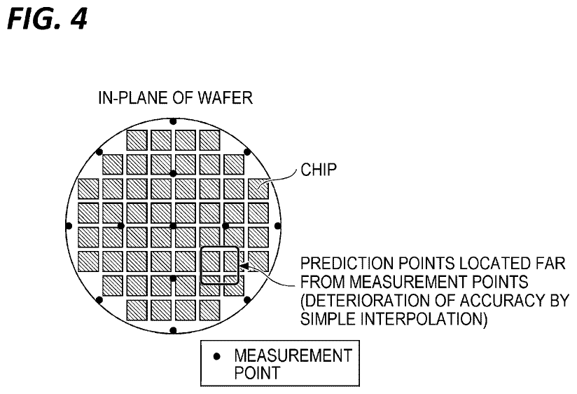

FIG. 4 is a view illustrating an example of a problem occurring in the substrate mass production process. FIG. 4 illustrates the relationship between the locations where chips are formed on the substrate and the 13 measurement points in the mass production process. As illustrated in FIG. 4, the entire film thickness of the locations where chips are formed cannot be measured from the 13 measurement points in the mass production process. The locations where chips are formed are examples of locations of importance in the quality control. However, in view of productivity, it is difficult to measure the entire film thickness of the locations of importance in the quality control such as the locations where chips are formed.

Further, the film thickness may be estimated by interpolation such as linear interpolation, but the accuracy of film thickness by the interpolation may deteriorate at prediction points located far from the measurement points. Further, at the 13 measurement points in the mass production process, it is necessary to rely on extrapolation as well due to the distribution of the measurement points, which may further deteriorate the accuracy of film thickness by the interpolation.

Therefore, in the present embodiment, the film thickness data of arbitrary coordinates are predicted with higher accuracy, from the film thickness data of the measurement points in the substrate mass production process, which are fewer than the number of measurement points in the substrate evaluation process.

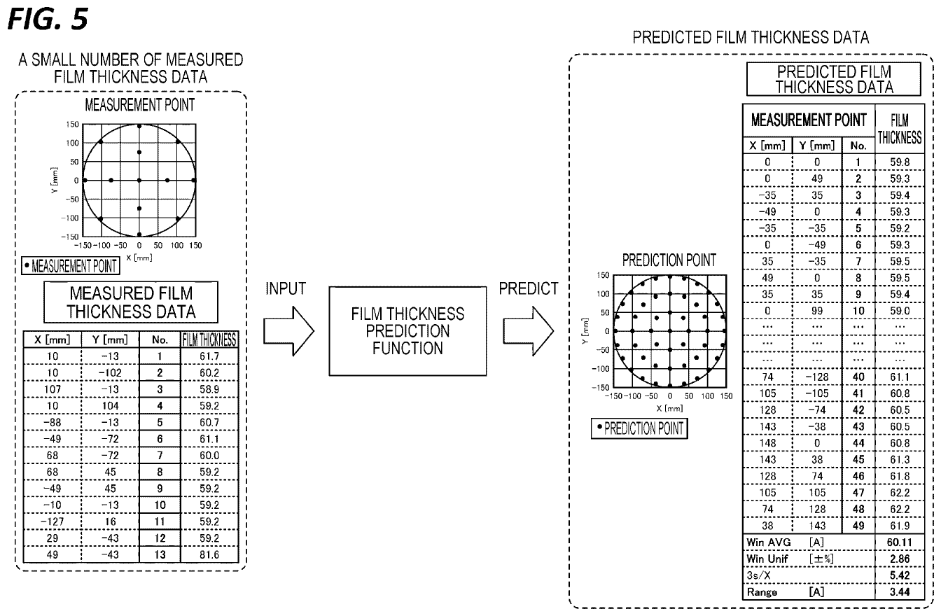

FIG. 5 is a view illustrating an example of a film thickness prediction function that predicts the film thickness data of arbitrary coordinates with higher accuracy from a small number of measured film thickness data. When measured film thickness data of the measurement points fewer than the number of prediction points are input, the film thickness prediction function of FIG. 5 generates a prediction model by regressing the input measured film thickness data using Zernike polynomials. By using the generated prediction model, the film thickness prediction function predicts film thickness data of arbitrary coordinates on the substrate. Details of the process performed by the film thickness prediction function will be described herein later.

In the present embodiment, as illustrated in FIG. 5, the film thickness data of desired coordinates may be predicted with higher accuracy, even from the measured thickness data of the measurement points fewer than the number of prediction points.

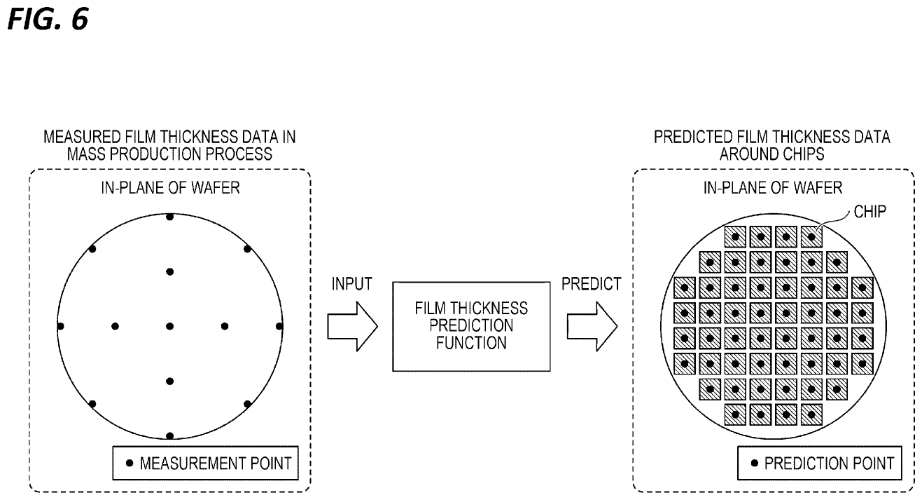

FIG. 6 is a view illustrating an example of a film thickness prediction function that predicts film thickness data around chips with higher accuracy from the measured film thickness data in the mass production process. When measured film thickness data of measurement points in the mass production process, which are fewer than the number of measurement points in the evaluation process, are input, the film thickness prediction function of FIG. 6 generates a prediction model by regressing the input measured film thickness data using the Zernike polynomials. By using the generated prediction model, the film thickness prediction function predicts the film thickness data around chips on the substrate. Details of the process performed by the film thickness prediction function will be described herein later.

In the present embodiment, as illustrated in FIG. 6, the film thickness data around each chip may be predicted with higher accuracy, even from the measured film thickness data in the mass production process, which are fewer than the number of prediction points. Therefore, in the present embodiment, analysis of correlation between the film thickness for each chip and the yield is possible, so that the quality control may be performed with higher accuracy.

### <Functional Configuration>

Hereinafter, descriptions will be made assuming an example where the apparatus controller 12 is an information processing apparatus, which predicts the film thickness data of a plurality of prediction points on the substrate surface using the prediction model, and outputs the predicted film thickness data. The server device 14 or the operator terminal 16 may be the information processing apparatus, which predicts the film thickness data of the plurality of prediction points on the substrate surface using the prediction model, and outputs the predicted film thickness data.

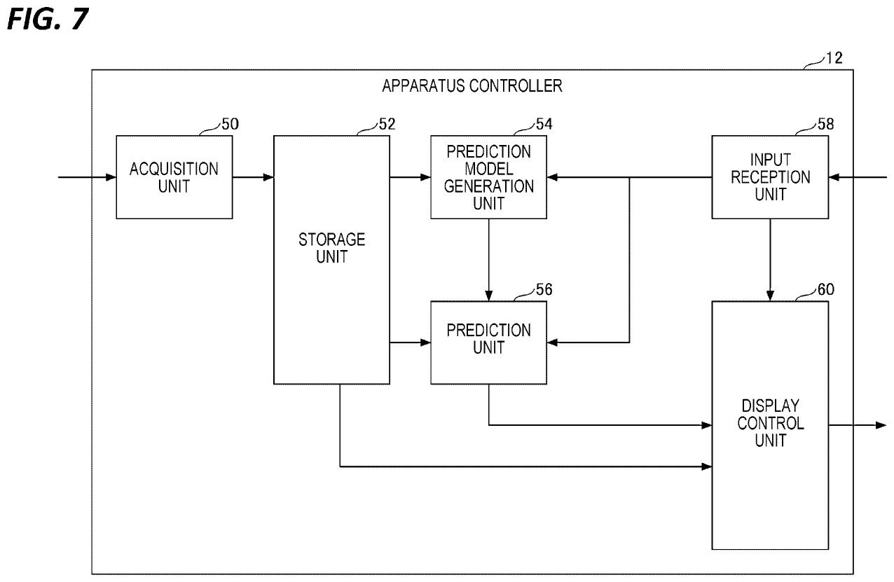

The apparatus controller 12 of the film thickness prediction system 1 according to the present embodiment is implemented by, for example, the functional blocks illustrated in FIG. 7. FIG. 7 is a functional block diagram illustrating an example of the apparatus controller 12 according to the present embodiment. The functional block diagram of FIG. 7 omits the illustration of components unnecessary for the description of the present embodiment.

By executing a program for the apparatus controller 12, the apparatus controller 12 illustrated in FIG. 7 implements an acquisition unit 50, a storage unit 52, a prediction model generation unit 54, a prediction unit 56, an input reception unit 58, and a display control unit 60.

The acquisition unit 50 acquires the measured film thickness data of the plurality of measurement points on the substrate surface with a film formed thereon by the substrate processing apparatus 10. The acquisition unit 50 acquires the measured film thickness data of the plurality of measurement points on the substrate surface from, for example, the measurement apparatus 11 or the database device 15. The acquisition unit 50 records the measured film thickness data of the plurality of measurement points on the substrate surface in the storage unit 52.

The prediction model generation unit 54 generates the prediction model by regressing the measured film thickness data using the Zernike polynomials as described herein later. The prediction unit 56 predicts the film thickness data of the plurality of prediction points on the substrate surface using the prediction model generated by the prediction model generation unit 54 as described herein later, and outputs the predicted film thickness data.

The input reception unit 58 receives various operations from the operator. For example, the operations received from the operator include an application startup operation and various operations on the started application. The input reception unit 58 notifies the contents of the various operations received from the operator to the prediction model generation unit 54, the prediction unit 56, and the display control unit 60. Further, the input reception unit 58 may receive an input of the plurality of prediction points on the substrate surface from the operator.

The display control unit 60 displays the predicted film thickness data output by the prediction unit 56 on the output device, according to the contents of the various operations by the operator. The display control unit 60 may display the predicted film thickness data of the plurality of prediction points on the substrate surface, which have been output by the prediction unit 56, in a table format, or in an image where the film thickness on the substrate surface is visualized in a distinguishable manner using, for example, colors.

### <Process>

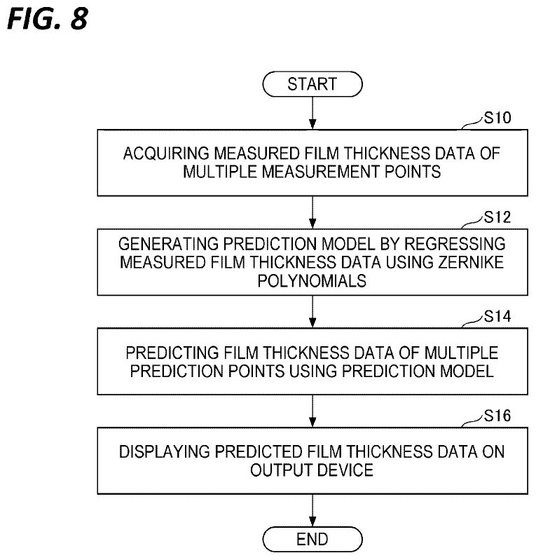

FIG. 8 is a flowchart illustrating an example of the process performed by the film thickness prediction system 1 according to the present embodiment.

In step S10, the acquisition unit 50 of the apparatus controller 12 acquires the measured film thickness data of the plurality of measurement points on the substrate surface with a film formed thereon by the substrate processing apparatus 10. For example, the acquisition unit 50 acquires the measured film thickness data of the plurality of measurement points on the substrate surface from the measurement apparatus 11. The acquisition unit 50 may acquire the measured film thickness data of the plurality of measurement points on the substrate surface, from the database device 15 that stores and manages the measured film thickness data of the plurality of measurement points on the substrate surface, which have been measured by the measurement apparatus 11. The acquisition unit 50 may acquire the measured film thickness data of the plurality of measurement points on the substrate surface, which have been measured by the measurement apparatus 11, via a portable storage device such as a USB memory.

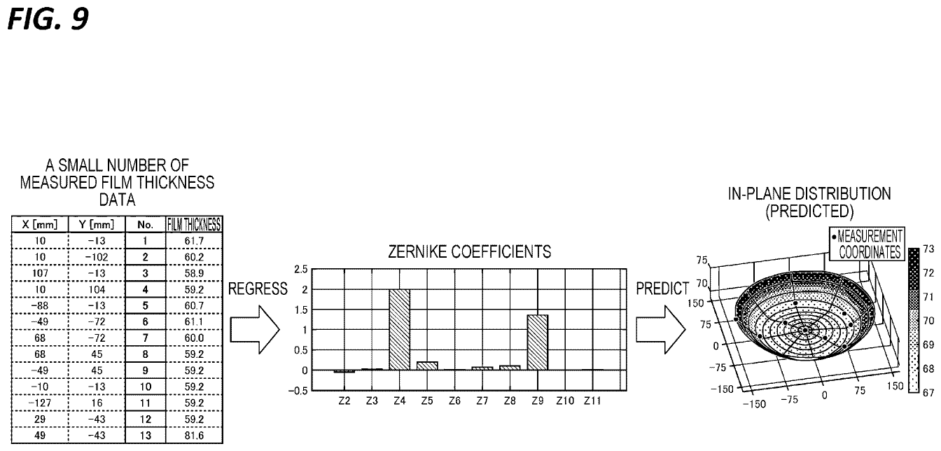

In step S12, the prediction model generation unit 54 of the apparatus controller 12 generates the prediction model by regressing the measured film thickness data using the Zernike polynomials. Here, details of the process of step S12 will be described with reference to FIGS. 9 through 13A to 13C.

FIGS. 9 through 13A to 13C are views illustrating an example of an algorithm of the film thickness prediction function.

The prediction model generation unit 54 generates the prediction model by regressing the measured film thickness data using the Zernike polynomials of Equation (1) below. In Equation (1), y represents the film thickness. X represents the design matrix. zᵢ represents the Zernike coefficient. λᵢ represents the normalization coefficient.

$$J ( z ) = {‖ y - X \cdot z ‖}_{2}^{2} + {\sum }_{i} {λ}_{i} \cdot {z}_{i}^{2} . \qquad ( 1 )$$

The design matrix X is constructed as follows. rᵢ is the radial distance of an i-th measurement point (e.g., normalized such that 0≤r≤1). θᵢ is the deflection angle of the i-th measurement point.

$$X := [ {Z}_{\text{?}} {Z}_{\text{?}} {Z}_{\text{?}} {Z}_{\text{?}} {Z}_{\text{?}} {Z}_{\text{?}} {Z}_{\text{?}} {Z}_{\text{?}} {Z}_{\text{?}} ]$$

$${Z}_{\text{?}} ( \text{?} , θ ) := 1 , {Z}_{\text{?}} ( \text{?} , θ ) := 2 \text{?} cos θ , {Z}_{\text{?}} ( \text{?} , θ ) := 2 \text{?} sin θ \text{?}$$

$${Z}_{\text{?}} ( \text{?} , θ ) := \sqrt{3} ( {\text{?}}^{2} - 1 ) , {Z}_{\text{?}} ( \text{?} , θ ) := \sqrt{6} {\text{?}}^{\text{?}} cos 2 θ , {Z}_{\text{?}} ( \text{?} , θ ) := \sqrt{6} {\text{?}}^{\text{?}} sin 2 θ ,$$

$${Z}_{\text{?}} ( \text{?} , θ ) := \sqrt{\text{?}} ( 6 {\text{?}}^{\text{?}} - 6 {\text{?}}^{\text{?}} + 1 ) , {Z}_{\text{?}} ( \text{?} , θ ) := \sqrt{\text{?}} {\text{?}}^{\text{?}} cos 3 θ , {Z}_{\text{?}} ( \text{?} , θ ) := \sqrt{8} {\text{?}}^{\text{?}} sin 3 θ$$

$${Z}_{\text{?}} = [ \begin{matrix}{Z}_{\text{?}} ( {\text{?}}_{\text{?}} , {θ}_{\text{?}} ) \\ ⋮ \\ {Z}_{\text{?}} ( {\text{?}}_{\text{?}} , {θ}_{\text{?}} )\end{matrix} ] , … , {Z}_{\text{?}} := [ \begin{matrix}{Z}_{\text{?}} ( {r}_{\text{?}} , {θ}_{\text{?}} ) \\ ⋮ \\ {Z}_{\text{?}} ( {\text{?}}_{\text{?}} , {θ}_{\text{?}} )\end{matrix} ]$$

$$\text{?} \text{indicates text missing or illegible when filed}$$

The prediction model generation unit 54 performs the regression (fitting) of the small number of measured film thickness data that have been acquired in step S10, using the Zernike polynomials. As illustrated in FIG. 9, the combination between Zernike coefficients obtained by regressing the small number of measured film thickness data acquired in step S10 using the Zernike polynomials, and the Zernike polynomials used for the regression is set as the prediction model, and the in-plane distribution of the film thickness on the substrate surface is predicted using the prediction model.

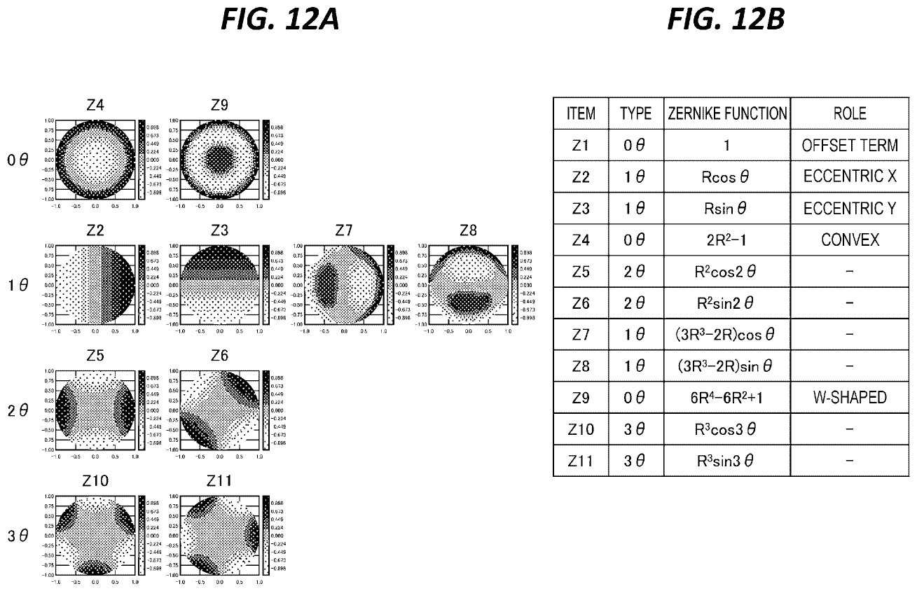

The Zernike coefficients used in the regression of step S10 have the features illustrated in FIGS. 12A and 12B. FIG. 12A represents examples of multiple in-plane profiles of the film thickness on the substrate surface. As illustrated in FIG. 12A, the Zernike coefficients Z1 to Z11 are associated with the multiple in-plane profiles of the film thickness on the substrate surface, respectively. For example, the Zernike coefficient Z4 is associated with the convex in-plane profile. The Zernike coefficient Z9 is associated with the W-shaped in-plane profile.

FIG. 12B represents examples of the features of the plurality of Zernike coefficients. The coordinates of the Zernike polynomials are in a polar coordinate system. As illustrated in FIG. 12B, the Zernike coefficients Z1 to Z11 are associated with types, Zernike functions, and roles.

The Zernike polynomials are orthogonal polynomials defined on the unit circle. In the present embodiment, by performing linear regression on the in-plane profiles of the film thickness on the substrate surface to be predicted, using the Zernike polynomials as basis functions, the features of the multiple in-plane profiles of the film thickness on the substrate surface may be extracted.

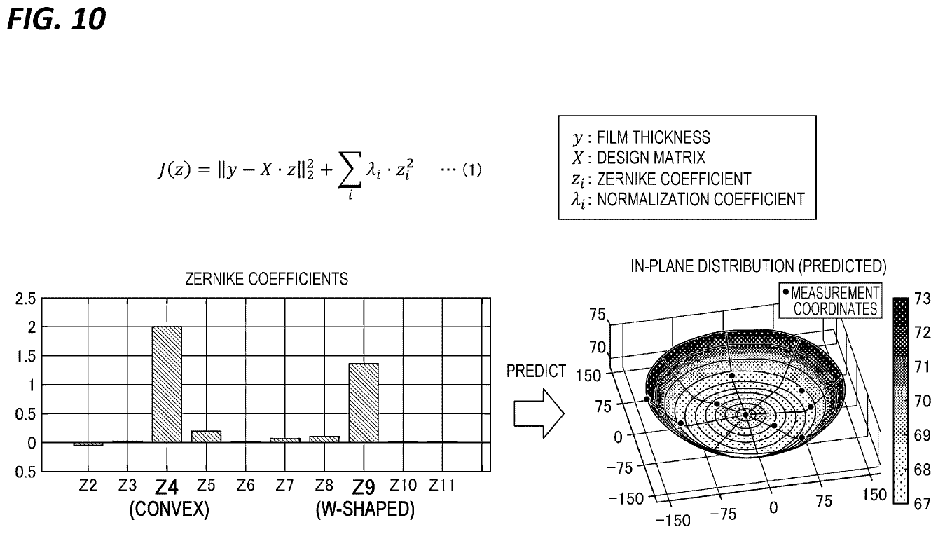

In Equation (1), in order to prevent overfitting even when the small number of measured film thickness data are available, the regression is performed by adding normalization terms as illustrated in FIG. 10. As represented in Equation (1), normalization coefficients λᵢ correspond to the normalization terms of the Zernike coefficients zᵢ, respectively. In Equation (1), the normalization coefficient λᵢ of the Zernike coefficient zᵢ of importance is decreased, and the normalization coefficients λᵢ of the other Zernike coefficients zᵢ are increased, so that the film thickness may be predicted with high accuracy while suppressing the overfitting.

By increasing the normalization coefficient 24 of the Zernike coefficient Z4 associated with the convex in-plane profile and the normalization coefficient 29 of the Zernike coefficient Z9 associated with the W-shaped in-plane profile, the present embodiment enables the prediction of the film thickness with high accuracy while suppressing the overfitting.

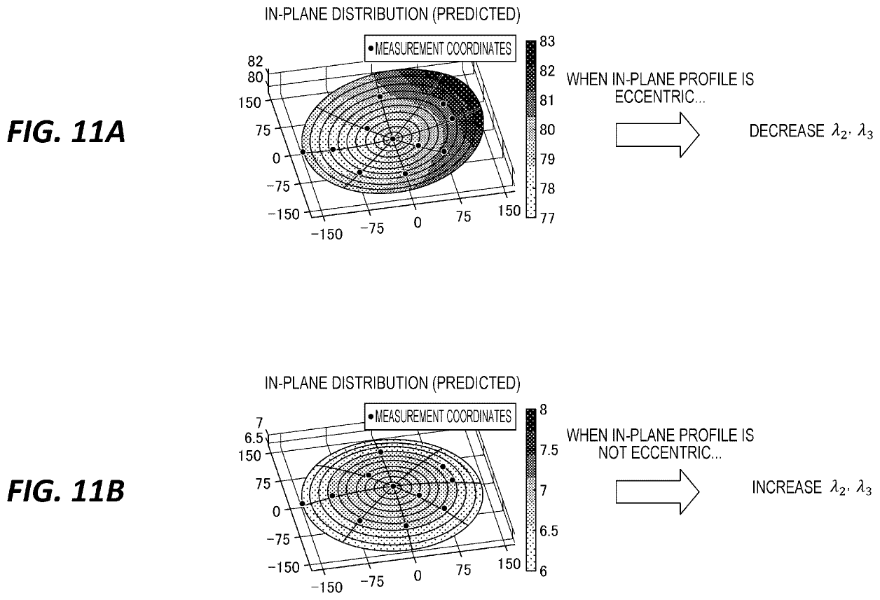

The adjustment of the normalization coefficients λᵢ of the Zernike coefficients zᵢ will be described with reference to FIGS. 11A and 11B. As illustrated in FIGS. 11A and 11B, by adjusting the normalization coefficients λᵢ of the Zernike coefficients zᵢ according to the in-plane profile of the film thickness on the substrate surface, the accuracy of the prediction by the prediction model that predicts the film thickness on the substrate surface improves. The adjustment of the normalization coefficients λᵢ of the Zernike coefficients zᵢ is performed by, for example, the operator.

FIG. 11A represents that when the in-plane profile of the film thickness on the substrate surface is eccentric, the normalization coefficient 22 of the Zernike coefficient Z2 and the normalization coefficient 23 of the Zernike coefficient Z3 are decreased, thereby improving the accuracy of the prediction by the prediction model that predicts the film thickness on the substrate surface.

FIG. 11B represents that when the in-plane profile of the film thickness on the substrate surface is not eccentric, the normalization coefficient 22 of the Zernike coefficient Z2 and the normalization coefficient 23 of the Zernike coefficient Z3 are increased, thereby improving the accuracy of the prediction by the prediction model that predicts the film thickness on the substrate surface.

The normalization coefficients 2 of the Zernike coefficients zᵢ may be adjusted using cross validation to minimize a mean squared error. For the adjustment of the normalization coefficients λᵢ of the Zernike coefficients zᵢ, for example, leave-one-outcross-validation may be used. Further, the adjustment of the normalization coefficients 2 of the Zernike coefficients zᵢ may be performed for each substrate processing apparatus 10 or for each process.

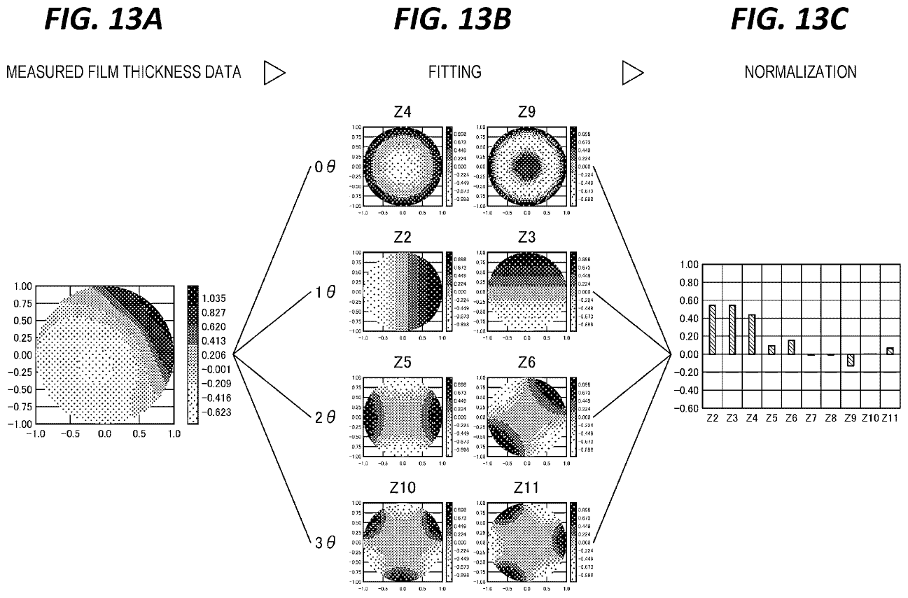

The process of regressing the measured film thickness data using the Zernike polynomials is illustrated in, for example, the images of FIGS. 13A to 13C. FIG. 13A is an image view representing the film thickness on the substrate surface based on the measured film thickness data (Raw data) in a distinguishable manner using, for example, colors. In step 12, the measured film thickness data illustrated in FIG. 13A are regressed using the Zernike polynomials having the Zernike coefficients zᵢ of FIG. 13B, thereby obtaining quantified Zernike coefficients Z2 to Z11 as illustrated in FIG. 13C. As illustrated in FIGS. 13A to 13C, the Zernike polynomials may quantitatively express the pattern of the in-plane profile of the film thickness on the substrate surface.

Returning to step S14 of FIG. 8, the prediction unit 56 of the apparatus controller 12 predicts the film thickness data of the plurality of prediction points on the substrate surface using the prediction model generated in step S12. The prediction unit 56 may predict, for example, the film thickness data of arbitrary coordinates (e.g., XY coordinates) on the substrate surface, which are input by the operator.

In step S16, the display control unit 60 displays the predicted film thickness data that have been predicted by the prediction unit 56 in step S14, on the output device 502 such as a display. The format to display the predicted film thickness data is not limited, and the predicted film thickness data may be displayed in a table form or in an image where the film thickness on the substrate surface is visualized in a distinguishable manner, using, for example, colors.

### <Validation>

The validation of the prediction model generated in the present embodiment was performed using film thickness data of 49 measurement points in the past evaluation process, as validation data. The validation method is performed as follows.

First, film thickness data of 13 measurement points are extracted from the validation data of the 49 measurement points, and are input into the prediction model, to predict film thickness data of 49 prediction points (hereinafter, referred to as predicted values).

Second, film thickness data of 49 measurement points (hereinafter, referred to as actual values) are extracted from the validation data of the 49 measurement points. Third, the actual values and the predicted values of the 49 points are compared to validate the accuracy of the prediction by the prediction model.

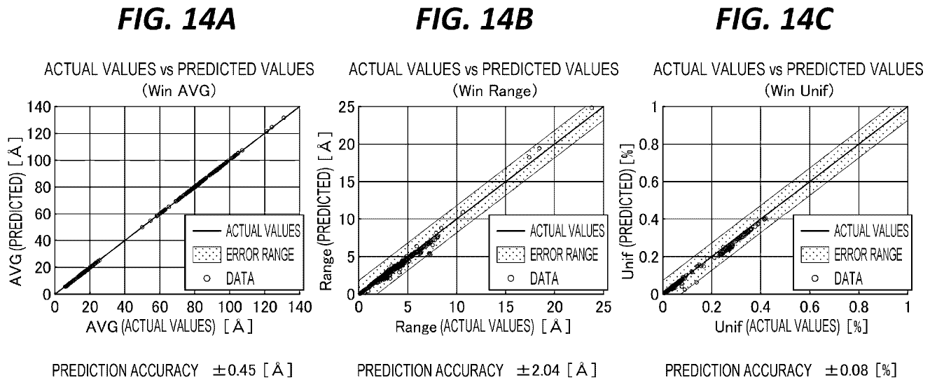

Fourth, the comparison of predicted values and actual values was conducted between statistical values of the in-plane film thickness of the substrate based on the actual values of the 49 points (e.g., film thickness average, Range, or in-plane uniformity) and statistical values of the in-plane film thickness of the substrate based on the predicted values of the 49 points. The result of the comparison of predicted values and actual values is provided in, for example, FIGS. 14A to 14C.

FIGS. 14A to 14C are graph views illustrating an example of the comparison of predicted values and actual values between the statistical values of the in-plane film thickness of the substrate based on the actual values of the 49 points and the statistical values of the in-plane film thickness of the substrate based on the predicted values of the 49 points.

FIG. 14A represents an example of the result of the comparison of predicted values and actual values for the film thickness average among the statistical values of the in-plane film thickness of the substrate. FIG. 14B represents an example of the result of the comparison of predicted values and actual values for the Range among the statistical values of the in-plane film thickness of the substrate. FIG. 14C represents an example of the result of the comparison of predicted values and actual values for the in-plane uniformity among the statistical values of the in-plane film thickness of the substrate. As illustrated in FIGS. 14A to 14C, the prediction model generated in the present embodiment may predict the statistical values of the in-plane film thickness of the substrate with high accuracy.

According to the present embodiment, it is possible to provide a technology, which predicts the film thickness data of a plurality of prediction points on the substrate surface with higher accuracy, from the measured film thickness data of a small number of measurement points. Further, according to the present embodiment, it is possible to predict the film thickness of arbitrary coordinates on the substrate surface with higher accuracy without increasing the number of measurement points. For example, in the present embodiment, since it is possible to predict the film thickness data of the greater number of measurement points (e.g., 49 points) than the small number of measurement points in the mass production process (e.g., 13 points), from the measured film thickness data of the small number of measurement points in the mass production process, the statistical values of the in-plane film thickness may be calculated with higher accuracy. Further, in the present embodiment, since the film thickness of arbitrary coordinates on the substrate surface may be predicted, the film thickness of the locations of importance in the quality control may also be predicted.

### Other Embodiments

For example, the film thickness prediction method according to the present embodiment may be applied to a substrate processing apparatus that measures or estimates the film thickness based on reflected light from the substrate. The substrate processing apparatus, which measures or estimates the film thickness based on reflected light from the substrate, is well-known as disclosed in, for example, Japanese Patent Laid-Open Publication No. 2022-181680. For example, the substrate processing apparatus disclosed in Japanese Patent Laid-Open Publication No. 2022-181680 is an example of a substrate processing apparatus including a measurement unit that measures the measured film thickness data of the plurality of measurement points on the substrate surface with a film formed thereon.

The substrate processing apparatus, which measures or estimates the film thickness based on reflected light from the substrate, measures or estimates the film thickness data of the small number of measurement points on the film-formed substrate surface, and generates the prediction model by regressing the measured or estimated film thickness data using the Zernike polynomials. The substrate processing apparatus, which measures or estimates the film thickness based on reflected light from the substrate, may predict the film thickness data of the greater number of measurement points than the small number of measurement points on the film-formed substrate surface by using the generated prediction model, output the predicted film thickness data, and display the predicted film thickness data on the output device 502. Further, the substrate processing apparatus may include a communication unit that receives the measured film thickness data of the plurality of measurement points on the film-formed substrate surface, thereby obtaining the measured film thickness data from the measurement apparatus 11. The substrate processing apparatus, which has obtained the measured film thickness data from the measurement apparatus 11, measures or estimates the film thickness data of the small number of measurement points on the film-formed substrate surface, and generates the prediction model by regressing the measured or estimated film thickness data using the Zernike polynomials. Then, the substrate processing apparatus may predict the film thickness data of the greater number of measurement points than the small number of measurement points on the film-formed substrate surface by using the generated prediction model, output the predicted film thickness data, and display the predicted film thickness data on the display device 502.

According to the present disclosure, it is possible to predict the film thickness data of a plurality of prediction points on the substrate surface with higher accuracy.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. An information processing apparatus comprising:
acquisition circuitry configured to acquire measured film thickness data of a plurality of measurement points on a substrate surface with a film formed thereon by a substrate processing apparatus;
prediction model generation circuitry configured to generate a prediction model by regressing the measured film thickness data using Zernike polynomials;
prediction circuitry configured to predict film thickness data of a plurality of prediction points on the substrate surface using the prediction model, and output the film thickness data predicted by the prediction circuitry as predicted film thickness data; and
display control circuitry configured to display the predicted film thickness data on an output device.

2. The information processing apparatus according to claim 1, wherein the prediction model generation circuitry generate the prediction model by regressing the measured film thickness data using Equation (1):
$$J ( z ) = {‖ y - X \cdot z ‖}_{2}^{2} + {\sum }_{i} {λ}_{i} \cdot {z}_{i}^{2} . \qquad ( 1 )$$
y: film thickness
X: design matrix
zᵢ: Zernike coefficient
λᵢ: Normalization coefficient.

3. The information processing apparatus according to claim 2, wherein the normalization coefficient λᵢ in Equation (1) is a value that is adjusted according to an in-plane profile of film thickness on the substrate surface.

4. The information processing apparatus according to claim 2, wherein the normalization coefficient λᵢ in Equation (1) is a value that is adjusted using cross validation to minimize a mean squared error.

5. The information processing apparatus according to claim 1, further comprising:
input reception circuitry configured to receive input of the plurality of prediction points on the substrate surface from an operator,
wherein the prediction circuitry predict the film thickness data of the plurality of prediction points input by the operator on the substrate surface.

6. The information processing apparatus according to claim 1, wherein the display control circuitry display in-plane distribution of film thickness on the substrate surface.

7. The information processing apparatus according to claim 1, wherein the prediction model generation circuitry generate the prediction model by regressing the measured film thickness data of the plurality of measurement points fewer than the plurality of prediction points on the substrate surface using Zernike polynomials.

8. A substrate processing apparatus comprising:
a processing chamber configured to accommodate a substrate and form a film on a surface of the substrate;
a stage disposed inside the processing chamber, and configured to support the substrate; and
a controller configured to control an overall operation of the substrate processing apparatus,
wherein the controller is configured to:
receive measured film thickness data of a plurality of measurement points on the surface of the substrate with the film formed thereon;
generate a prediction model by regressing the measured film thickness data using Zernike polynomials;
predict film thickness data of a plurality of prediction points on the surface of the substrate using the prediction model, and output the predicted film thickness data; and
display the predicted film thickness data on an output device.

9. The substrate processing apparatus according to claim 8, wherein the process is further configured to measure the measured film thickness data of the plurality of measurement points on the surface of the substrate with the film formed thereon.

10. A film thickness prediction method performed by an information processing apparatus, the film thickness prediction method comprising:
acquiring measured film thickness data of a plurality of measurement points on a substrate surface with a film formed thereon by the substrate processing apparatus;
generating a prediction model by regressing the measured film thickness data using Zernike polynomials; and
predicting film thickness data of a plurality of prediction points on the substrate surface using the prediction model, and outputting the film thickness data predicted in the predicting of the film thickness data as predicted film thickness data; and
displaying the predicted film thickness data on an output device.
